(19) United States
(12) Patent Application Publication
(10) Pub. No.: US 2012/0098017 A1
(43) Pub. Date: Apr. 26, 2012

(54) LIGHT EMITTING MODULE, METHOD OF PRODUCING LIGHT-EMITTING MODULE, AND LIGHTING FIXTURE UNIT

(75) Inventors: Takaaki Komatsu, Shizuoka (JP); Hisayoshi Daicho, Shizuoka (JP); Yasuaki Tsutsumi, Shizuoka (JP); Yasutaka Sasaki, Shizuoka (JP)

(73) Assignee: KOITO MANUFACTURING CO., LTD., Tokyo (JP)

(21) Appl. No.: 13/320,500

(22) PCT Filed: Mar. 11, 2010
(86) PCT No.: PCT/JP2010/001747

§ 371 Date: Jan. 3, 2012

(30) Foreign Application Priority Data
May 15, 2009 (JP) 2009-118695

(51) Int. Cl. H01L 33/50

(52) U.S. Cl. 257/98; 438/29; 257/E33.06

(57) ABSTRACT

In a light emitting module, each of a first light wavelength conversion member, a second light wavelength conversion member, and a third light wavelength conversion member converts the wavelength of the light emitted by a semiconductor light emitting element to emit the light within a wavelength range different from the others. Each of the first light wavelength conversion member, the second light wavelength conversion member, and the third light wavelength conversion member is formed into a plate shape and is laminated such that the light emitted by the semiconductor light emitting element passes through each of them in descending order of the average wavelength of the light whose wavelength has been converted.

### FIELD OF THE INVENTION

The present invention relates to a light emitting module, a method of manufacturing the light emitting module, and a lamp unit comprising the light emitting module.

### BACKGROUND ART

In recent years, for the purpose of long life or reduction in power consumption, techniques have been developed in each of which a light emitting module having a light emitting element, such as an LED (Light Emitting Diode), is adopted as a light source for emitting strong light, such as a lamp unit that emits light toward the front of a vehicle. However, the light emitting module to be used in such an application is required not only to achieve white light emission but also to have high luminance and high light intensity. Accordingly, in order to enhance, for example, the extraction efficiency of white light, a lighting system comprising: a light emitting element mainly emitting blue light; a yellow phosphor mainly emitting yellow light by being excited with the blue light; and a blue-transmitting yellow-reflecting means that transmits the blue light from the light emitting element and reflects the light with a wavelength of the yellow light or more from the yellow phosphor, is proposed (see, for example, Patent Document 1). In addition, in order to increase, for example, a conversion efficiency, a structure comprising a ceramic layer arranged within the channel of the light emitted by a light emitting layer is proposed (see, for example, Patent Document 2).
[Patent Document 1] Japanese Patent Application Publication No. 2007-59864
[Patent Document 2] Japanese Patent Application Publication No. 2006-5367

### DISCLOSURE OF THE INVENTION

### Problems to be Solved by the Invention

In a light emitting module in which a light wavelength conversion layer using particulate phosphors is provided, as described in, for example, the aforementioned Patent Document 1, the light emitted by a light emitting element is scattered on the surfaces of the particular phosphors while the light is passing through the light wavelength conversion layer. Such scattering of light causes the heat generation of a light wavelength conversion layer, etc., and as a result of that, there is the fear that the light intensity of the light emitted from the light wavelength conversion layer may be decreased.

On the other hand, in order to meet a wide variety of applications and the demands from market, it is now demanded to develop a light wavelength conversion layer in which emitted light with desired color can be obtained by appropriately setting the wavelength to be converted. A technique can be considered as a method of providing such a light wavelength conversion layer, in which a light wavelength conversion layer using multiple types of phosphors is provided. However, there are sometimes the cases where multiple types of phosphors each having a light wavelength conversion property different from the others have melting points and sintering reaction temperatures, etc., different from each other. Accordingly, when ceramic is formed by sintering phosphors as in a light emitting module described, for example, in the aforementioned Patent Document 2, there is the possibility that appropriate sintering of multiple types of phosphors becomes difficult due to the difference in their properties, even if the multiple types of phosphors are intended to be contained in a light wavelength conversion member to obtain emitted light with desired color.

Therefore, the present invention has been made to solve the aforementioned problem, and a purpose of the invention is to provide a light emitting module in which the color of emitted light can be appropriately set while a decrease in the light intensity of the light is being suppressed.

### Means for Solving the Problem

In order to solve the aforementioned problem, a light emitting module according to an embodiment of the present invention comprises: a light emitting element; and a plurality of light wavelength conversion members each of which converts the wavelength of the light emitted by the light emitting element to emit light within a wavelength range different from the others. Each of the plurality of light wavelength conversion members is formed into a plate shape before the lamination thereof and is laminated such that the light emitted by the light emitting element sequentially passes through each of them.

According to the embodiment, individual light wavelength conversion members can be formed by using each of a plurality of light wavelength conversion materials from which simultaneous formation into a plate shape by, for example, sintering, etc. Further, by laminating, one on another, the plurality of plate-shaped light wavelength conversion members thus formed, the color of emitted light can be appropriately set. In addition, each of the light wavelength conversion members may be formed to be so transparent that the total light transmittance of the light within a conversion wavelength range is 40 percent or more.

The plurality of light wavelength conversion members may be laminated one on another such that the light emitted by the light emitting element passes through the members in descending order of the average wavelength of the light whose wavelength has been converted.

It is known that a light wavelength conversion member can convert the wavelength of light only in a manner in which the converted wavelength is longer than that before the conversion. According to the embodiment, it can be avoided that the wavelength of light, which has been converted by any one of the plurality of light wavelength conversion members, may be converted again by the subsequent light wavelength conversion member. Accordingly, it becomes possible to easily and appropriately set the color of the light emitted by the light emitting module.

Among the plurality of light wavelength conversion members, at least one of the members through which the light emitted by the light emitting element passes for the second time or later may be provided so as to cover approximately the whole area of the light emitting portion in the light wavelength conversion member through which the light emitted by the light emitting element passes last.

According to the embodiment, it can be avoided that the light, which has passed through the light wavelength conversion member arranged upstream of the plurality of light wavelength conversion members, may be emitted outward without passing through the light wavelength conversion member arranged downstream thereof. Accordingly, the wavelength of the light emitted by the light emitting element can be approximately converted by the plurality of light wavelength conversion members.

Among the plurality of light wavelength conversion members, at least one pair of the members to be bonded together may have concavities and convexities in the bonded portion between them. According to the embodiment, the extraction efficiency of light can be enhanced by the concavities and convexities in the bonded portion. Accordingly, it becomes possible to provide a light emitting module in which a decrease in the light intensity of emitted light is suppressed while the color of the emitted light is being appropriately set.

Another embodiment of the present invention is a method of manufacturing a light emitting module. The method comprises: laminating, one on another, a plurality of light wavelength conversion members each of which is formed into a plate shape and each of which converts the wavelength of the incident light to emit the light within a wavelength range different from the others; and arranging the plurality of light wavelength conversion members thus laminated such that the light emitted by a light emitting element sequentially passes through each of them.

According to the embodiment, by laminating beforehand a plurality of light wavelength conversion members, it becomes possible to easily laminate the plurality of light wavelength conversion members on a light emitting element. Accordingly, a light emitting module can be easily manufactured in which the color of emitted light is appropriately set.

Still another embodiment of the present invention is a lamp unit. The lamp unit comprises: a light emitting module including a light emitting element and a plurality of light wavelength conversion members each of which converts the wavelength of the light emitted by the light emitting element to emit the light within a wavelength range different from the others; and an optical member configured to collect the light emitted by the light emitting module. Each of the plurality of light wavelength conversion members is formed into a plate shape before the lamination thereof and is laminated such that the light emitted by the light emitting element sequentially passes through each of them.

According to the embodiment, a lamp unit can be provided by using a light emitting module in which the color of emitted light is appropriately set. Accordingly, a lamp unit can be provided from which the light with color meeting an application and the demands from market is emitted.

### Advantage of the Invention

According to the present invention, a light emitting module can be provided in which the color of emitted light can be appropriately set while a decrease in the light intensity thereof is being suppressed.

### BRIEF DESCRIPTION OF THE DRAWINGS

FIG. 1 is a sectional view illustrating the configuration of an automotive headlamp according to a first embodiment;

FIG. 2 is a view illustrating the configuration of a light emitting module substrate according to the first embodiment;

FIG. 3 is a side view of the light emitting module according to the first embodiment;

FIG. 4 is a graph illustrating an emission spectrum of each of a semiconductor light emitting element, a first light wavelength conversion member, and a second light wavelength conversion member;

FIG. 5 is a side view of a light emitting module according to a second embodiment;

FIG. 6 is a side view of a light emitting module according to a third embodiment;

FIG. 7 is a side view of a light emitting module according to a fourth embodiment;

FIG. 8 is a graph illustrating an emission spectrum of each of a semiconductor light emitting element, a first light wavelength conversion member, a second light wavelength conversion member, and a third light wavelength conversion member;

FIG. 9 is a side view of a light emitting module according to a fifth embodiment; and

FIG. 10 is a sectional view of a light emitting module according to a sixth embodiment.

### REFERENCE NUMERALS

10 AUTOMOTIVE HEADLAMP
16 LAMP UNIT
30 PROJECTION LENS
34 REFLECTOR
40 LIGHT EMITTING MODULE
48 SEMICONDUCTOR LIGHT EMITTING ELEMENT
52 LIGHT WAVELENGTH CONVERSION UNIT
54 FIRST LIGHT WAVELENGTH CONVERSION MEMBER
56 SECOND LIGHT WAVELENGTH CONVERSION MEMBER

### BEST MODE FOR CARRYING OUT THE INVENTION

Preferred embodiments of the present invention will now be described in detail with reference to accompanying drawings.

### First Embodiment

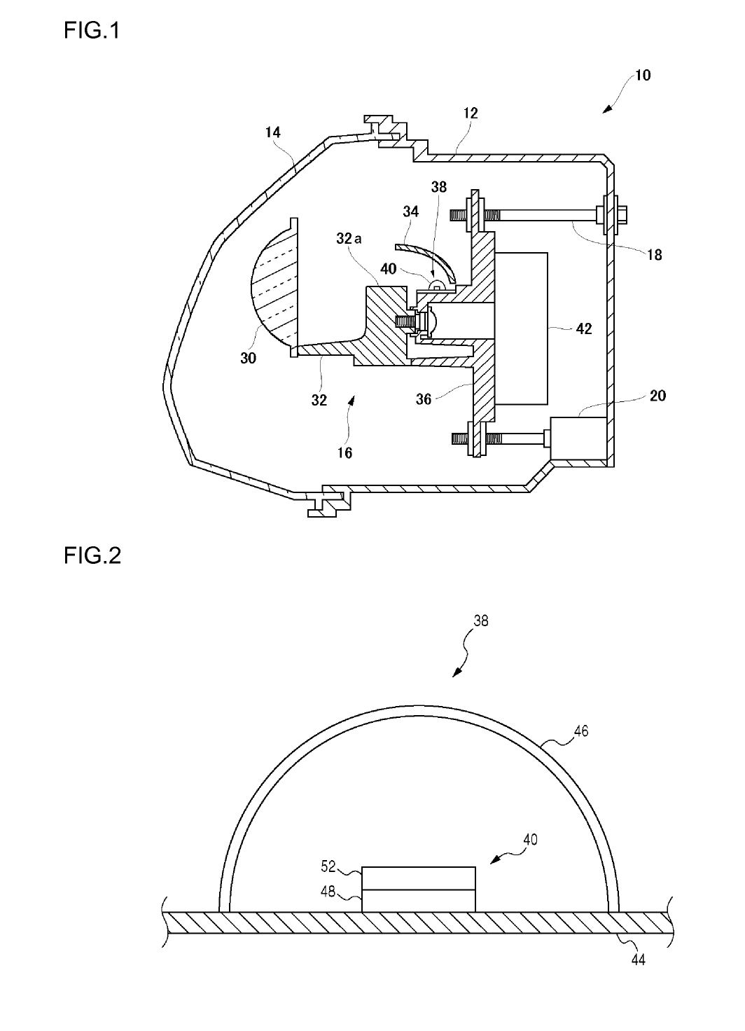

FIG. 1 is a sectional view illustrating the configuration of an automotive headlamp 10 according to a first embodiment. The automotive headlamp 10 has a lamp body 12, a front cover 14, and a lamp unit 16. Hereinafter, descriptions will be made, assuming that the left side in FIG. 1 is the front of the lamp and the right side therein is the back thereof. In addition, when viewing the front of the lamp, the right side is referred to as the right side of the lamp and the left side as the left side thereof. FIG. 1 illustrates the cross section of the automotive headlamp 10 cut by the vertical plane including the light axis of the lamp unit 16, when viewed from the left side of the lamp. When the automotive headlamp 10 is to be mounted in a vehicle, the automotive headlamps 10, which are formed symmetrically with each other, are provided in the left and right front portions of the vehicle, respectively. FIG. 1 illustrates the configuration of either of the left and right automotive headlamps 10.

The lamp body 12 is formed into a box shape having an opening. The front cover 14 is formed into a bow shape with a resin having translucency or glass. The front cover 14 is installed such that the edge thereof is attached to the opening of the lamp body 12. In such a manner, a lamp chamber is formed in the area covered with the lamp body 12 and the front cover 14.

The lamp unit 16 is arranged in the lamp chamber. The lamp unit 16 is fixed to the lamp body 12 with aiming screws 18. The aiming screw 18 in the lower portion is configured to be rotatable by an operation of a leveling actuator 20. Accordingly, the light axis of the lamp unit 16 can be moved in the up-down direction by operating the leveling actuator 20.

The lamp unit 16 has a projection lens 30, a support member 32, a reflector 34, a bracket 36, a light emitting module substrate 38, and a radiating fin 42. The projection lens 30 is composed of a plano-convex aspheric lens, the front surface of which is convex-shaped and the back surface of which is flat-shaped, and projects a light source image that is formed on the back focal plane toward the front of the vehicle as an inverted image. The support member 32 supports the projection lens 30. A light emitting module 40 is provided on the light emitting module substrate 38. The reflector 34 reflects the light emitted from the light emitting module 40 to form the light source image on the back focal plane of the projection lens 30. As stated above, the reflector 34 and the projection lens 30 function as optical members that collect the light emitted by the light emitting module 40 toward the front of the lamp. The radiating fin 42 is installed onto the back surface of the bracket 36 to radiate the heat mainly generated by the light emitting module 40.

A shade 32a is formed on the support member 32. The automotive headlamp 10 is used as a light source for low-beam, and the shade 32a forms, in front of the vehicle, a cut-off line in the light distribution pattern for low-beam by shielding part of the light that has been emitted from the light emitting module 40 and reflected by the reflector 34. Because the light distribution pattern for low-beam is publicly known, descriptions thereof will be omitted.

FIG. 2 is a view illustrating the configuration of the light emitting module substrate 38 according to the first embodiment. The light emitting module substrate 38 has the light emitting module 40, a substrate 44, and a transparent cover 46. The substrate 44 is a printed circuit board, and the light emitting module 40 is attached to the upper surface thereof. The light emitting module 40 is covered with the colorless transparent cover 46. In the light emitting module 40, a semiconductor light emitting element 48 is attached directly on the substrate 44 and a light wavelength conversion unit 52 is arranged on the semiconductor light emitting element 48.

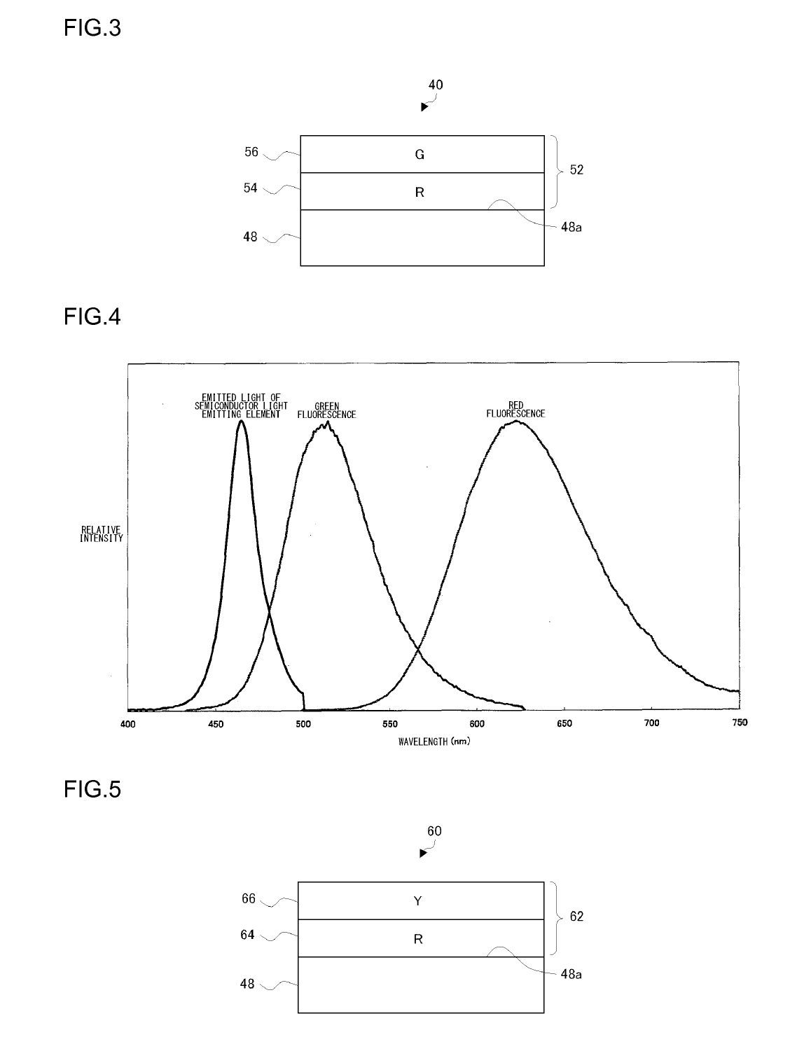

FIG. 3 is a side view of the light emitting module 40 according to the first embodiment. The semiconductor light emitting element 48 is composed of an LED element. In the first embodiment, a blue LED mainly emitting the light with a blue wavelength is adopted as the semiconductor light emitting element 48. Specifically, the semiconductor light emitting element 48 is composed of an InGaN LED element that is formed by making an InGaN semiconductor layer undergo crystal growth. The semiconductor light emitting element 48 is formed as, for example, a chip of 1 mm×1 mm and is provided such that the central wavelength of emitted blue light is made to be 470 nm. It is needless to say that the configuration of the semiconductor light emitting element 48 and the wavelength of the emitted light are not limited to what have been stated above, and an LED mainly emitting the light with a wavelength other than blue may be adopted as the semiconductor light emitting element 48.

A light emitting element of a so-called flip-chip type is adopted as the semiconductor light emitting element 48. It is needless to say that a light emitting element of another type can be adopted as the semiconductor light emitting element 48. For example, a light emitting element of a so-called vertical type or a so-called face-up type may be adopted as the semiconductor light emitting element 48.

The light wavelength conversion unit 52 has a first light wavelength conversion member 54 and a second light wavelength conversion member 56. It is needless to say that the number of light wavelength conversion members to be laminated is not be limited to two, and, the light wavelength conversion unit 52 may be composed of, for example, three layers or more of light wavelength conversion members.

Each of the first light wavelength conversion member 54 and the second light wavelength conversion member 56 is so-called luminescence ceramic or fluorescent ceramic, and can be obtained by sintering a ceramic green body made of YAG (Yttrium Aluminum Garnet) powder that is a phosphor to be excited by blue light. Because a method of manufacturing such light wavelength conversion ceramic is publicly known, detailed descriptions thereof will be omitted.

In addition, a transparent light wavelength conversion member is adopted as each of the first light wavelength conversion member 54 and the second light wavelength conversion member 56. The “transparent” in the first embodiment means that the total light transmittance of the light within a conversion wavelength range is 40 percent or more. As a result of intensive research and development by the present inventors, it has been found that, when a light wavelength conversion member is so transparent that the total light transmittance of the light within a conversion wavelength range is 40 percent or more, the wavelength of light can be appropriately converted by each of the first light wavelength conversion member 54 and the second light wavelength conversion member 56 and a decrease in the light intensity of the light passing through each of them can be appropriately suppressed. Accordingly, the light emitted by the semiconductor light emitting element 48 can be more efficiently converted by making each of the first light wavelength conversion member 54 and the second light wavelength conversion member 56 to be transparent, as stated above.

Each of the first light wavelength conversion member 54 and the second light wavelength conversion member 56 is composed of an inorganic substance free of an organic binder such that the durability thereof is enhanced in comparison with the case where an organic substance, such as an organic binder, is contained. Accordingly, it becomes possible to supply the power of, for example, 1 W or more to the light emitting module 40, and hence the luminance, light intensity, and luminous flux of the light emitted by the light emitting module 40 can be enhanced.

The first light wavelength conversion member 54 converts the wavelength of the blue light mainly emitted by the semiconductor light emitting element 48 to emit red light. The second light wavelength conversion member 56 converts the wavelength of the blue light to emit green light. Thus, each of the first light wavelength conversion member 54 and the second light wavelength conversion member 56 converts the wavelength of the light emitted by the semiconductor light emitting element 48 to emit the light within a wavelength range different from each other. Accordingly, white light, synthesized light made from: the blue light that has passed through the light wavelength conversion unit 52 as it is; the red light whose wavelength has been converted by the first light wavelength conversion member 54 to be emitted; and the green light whose wavelength has been converted by the second light wavelength conversion member 56 to be emitted, is emitted from the light emitting module 40.

In this case, two phosphors having properties different from each other can be separately sintered by forming the first light wavelength conversion member 54 and the second light wavelength conversion member 56 as separate phosphor ceramic. Accordingly, each of the first light wavelength conversion member 54 and the second light wavelength conversion member 56 can be appropriately formed as plate-shaped ceramic. Alternatively, each of the first light wavelength conversion member 54 and the second light wavelength conversion member 56 may be formed as a plated-shaped member made of a material other than ceramic.

FIG. 4 is a graph illustrating an emission spectrum of each of the semiconductor light emitting element 48, the first light wavelength conversion member 54, and the second light wavelength conversion member 56. In FIG. 4, “Red Fluorescence” indicates the emission spectrum of the first light wavelength conversion member 54 and “Green Fluorescence” indicates that of the second light wavelength conversion member 56. As illustrated in FIG. 4, the emission spectrum of each of the semiconductor light emitting element 48, the first light wavelength conversion member 54, and the second light wavelength conversion member 56, has a single mount shape. The average wavelength of the emission spectrum of the second light wavelength conversion member 56 is longer than that of the emission spectrum of the semiconductor light emitting element 48. In addition, the average wavelength of the emission spectrum of the first light wavelength conversion member 54 is longer than that of the emission spectrum of the second light wavelength conversion member 56. Because a method of calculating an average wavelength is publicly known, description thereof will be omitted.

Referring back to FIG. 3, each of the first light wavelength conversion member 54 and the second light wavelength conversion member 56 is laminated such that the light emitted by the semiconductor light emitting element 48 passes through each of them in descending order of the average wavelength of the light whose wavelength has been converted. Specifically, because the wavelength of red light is longer than that of green light, the first light wavelength conversion member 54 for emitting red light by converting a wavelength is arranged above the light emitting surface 48a of the semiconductor light emitting element 48, and the second light wavelength conversion member 56 is arranged further above the first light wavelength conversion member 54. A light wavelength conversion member can convert the wavelength of light only in a manner in which the converted wavelength is longer than that before the conversion. By arranging a plurality of light wavelength conversion members in descending order of the average wavelength of light, as stated above, it can be avoided that the wavelength of light, which has once been converted, may be converted again. Thereby, the color of the light emitted by the light emitting module 40 can be easily adjusted.

When the light emitting module 40 is manufactured, the first light wavelength conversion member 54 and the second light wavelength conversion member 56 are first laminated one on another by fixing them together with adhesive, etc., thereby forming the light wavelength conversion unit 52. Subsequently, the light wavelength conversion unit 52 is attached to the semiconductor light emitting element 48 by fixing the first light wavelength conversion member 54, the wavelength of light converted by which is longer, to the light emitting surface 48a of the semiconductor light emitting element 48 with adhesive, etc. Thereby, the light wavelength conversion unit 52 can be attached to the semiconductor light emitting element 48 such that the light emitted by the semiconductor light emitting element 48 sequentially passes through the first light wavelength conversion member 54 and the second light wavelength conversion member 56 in this order.

It is needless to say that the bonding between the first light wavelength conversion member 54 and the second light wavelength conversion member 56 or between the first light wavelength conversion member 54 and the semiconductor light emitting element 48 should not be limited to adhesion. For example, plasma bonding or mechanical bonding, such as caulking, may be adopted. Further, a space may be provided between the first light wavelength conversion member 54 and the semiconductor light emitting element 48. Alternatively, a reflective layer may be provided on each of the side surfaces of the first light wavelength conversion member 54 and the second light wavelength conversion member 56 by vapor-depositing, for example, aluminum, silver, or the like, in order to suppress a decrease in the light intensity of the light emitted upward of the light emitting module 40.

### Second Embodiment

FIG. 5 is a side view of a light emitting module 60 according to a second embodiment. The configuration of an automotive headlamp 10 is the same as that of the first embodiment, except that the light emitting module 60 is provided instead of the light emitting module 40. Hereinafter, the parts similar to the first embodiment will be denoted with the same reference numerals and descriptions thereof will be omitted.

The light emitting module 60 has a semiconductor light emitting element 48 and a light wavelength conversion unit 62. The light wavelength conversion unit 62 has a first light wavelength conversion member 64 and a second light wavelength conversion member 66. The first light wavelength conversion member 64 and the second light wavelength conversion member 66 are the same as the first light wavelength conversion member 54 and the second light wavelength conversion member 56 according to the first embodiment in that: they are made of fluorescent ceramic; they are formed to be plate-shaped and transparent; and they are composed of an inorganic substance free of an organic binder, etc.

The first light wavelength conversion member 64 converts the wavelength of the blue light mainly emitted by the semiconductor light emitting element 48 to emit red light. The second light wavelength conversion member 66 converts the wavelength of the blue light to emit yellow light. Thus, each of the first light wavelength conversion member 64 and the second light wavelength conversion member 66 converts the wavelength of the light emitted by the semiconductor light emitting element 48 to emit the light within a wavelength range different from each other. Accordingly, synthesized light made from: the blue light that has passed through the light wavelength conversion unit 62 as it is; the red light whose wavelength has been converted by the first light wavelength conversion member 64 to be emitted; and the yellow light whose wavelength has been converted by the second light wavelength conversion member 66 to be emitted, is emitted from the light emitting module 60.

It is possible to emit white light by combining blue light and yellow light. However, it is sometimes requested for such synthesized light to include red component into the emitted light in order to make the color look brighter. According to the light emitting module 60, a light emitting module for brightly lighting up an object to be irradiated by including red component into white light can be formed by laminating the first light wavelength conversion member 64 and the second light wavelength conversion member 66 one on another.

Also, in the second embodiment, each of the first light wavelength conversion member 64 and the second light wavelength conversion member 66 is laminated such that the light emitted by the semiconductor light emitting element 48 passes through each of them in descending order of the average wavelength of the light whose wavelength has been converted, in order to avoid that the wavelength of light, which has once been converted, may be converted again. Specifically, because the wavelength of red light is longer than that of yellow light, the first light wavelength conversion member 64 for emitting red light by converting a wavelength is arranged above the light emitting surface 48a of the semiconductor light emitting element 48, and the second light wavelength conversion member 66 is arranged further above the first light wavelength conversion member 64.

When the light emitting module 60 is manufactured, the first light wavelength conversion member 64 and the second light wavelength conversion member 66 are first laminated one on another by fixing them together with adhesive, etc., thereby forming the light wavelength conversion unit 62. Subsequently, the light wavelength conversion unit 62 is attached to the semiconductor light emitting element 48 by fixing the first light wavelength conversion member 64, the wavelength of light converted by which is longer, to the light emitting surface 48a of the semiconductor light emitting element 48 with adhesive, etc. Thereby, the light wavelength conversion unit 62 can be attached to the semiconductor light emitting element 48 such that the light emitted by the semiconductor light emitting element 48 sequentially passes through the first light wavelength conversion member 64 and the second light wavelength conversion member 66 in this order.

The second embodiment is the same as the first embodiment in that: a space may be provided between the first light wavelength conversion member 64 and the semiconductor light emitting element 48; and a reflective layer may be provided on each of the side surfaces of the first light wavelength conversion member 64 and the second light wavelength conversion member 66.

### Third Embodiment

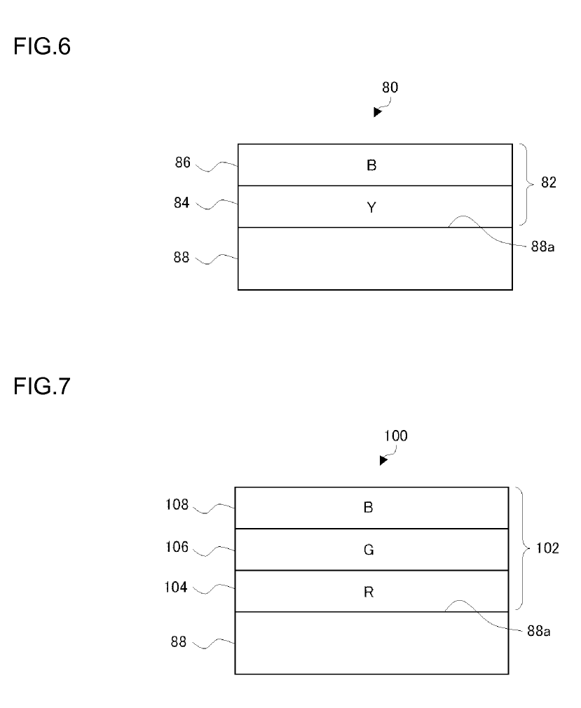

FIG. 6 is a side view of a light emitting module 80 according to a third embodiment. The configuration of an automotive headlamp 10 is the same as that of the first embodiment, except that the light emitting module 80 is provided instead of the light emitting module 40. Hereinafter, the parts similar to the first embodiment will be denoted with the same reference numerals and descriptions thereof will be omitted.

The light emitting module 80 has a semiconductor light emitting element 88 and a light wavelength conversion unit 82. The semiconductor light emitting element 88 is formed in the same way as the semiconductor light emitting element 48 according to the first embodiment, except that the semiconductor light emitting element 88 emits ultraviolet light. The light wavelength conversion unit 82 has a first light wavelength conversion member 84 and a second light wavelength conversion member 86. The first light wavelength conversion member 84 and the second light wavelength conversion member 86 are the same as the first light wavelength conversion member 54 and the second light wavelength conversion member 56 according to the first embodiment in that: they are made of fluorescent ceramic; they are formed to be plate-shaped and transparent; and they are composed of an inorganic substance free of an organic binder, etc.

The first light wavelength conversion member 84 converts the wavelength of the ultraviolet light mainly emitted by the semiconductor light emitting element 88 to emit yellow light. The second light wavelength conversion member 86 converts the wavelength of the ultraviolet light to emit blue light. Thus, each of the first light wavelength conversion member 84 and the second light wavelength conversion member 86 converts the wavelength of the light emitted by the semiconductor light emitting element 88 to emit the light within a wavelength range different from each other. Accordingly, white light, synthesized light made from: the yellow light whose wavelength has been converted by the first light wavelength conversion member 84 to be emitted; and the blue light whose wavelength has been converted by the second light wavelength conversion member 86 to be emitted, is emitted from the light emitting module 80.

Also, in the third embodiment, each of the first light wavelength conversion member 84 and the second light wavelength conversion member 86 is laminated such that the light emitted by the semiconductor light emitting element 88 passes through each of them in descending order of the average wavelength of the light whose wavelength has been converted, in order to avoid that the wavelength of light, which has once been converted, may be converted again. Specifically, because the wavelength of yellow light is longer than that of blue light, the first light wavelength conversion member 84 for emitting yellow light by converting a wavelength is arranged above the light emitting surface 88a of the semiconductor light emitting element 88, and the second light wavelength conversion member 86 is arranged further above the first light wavelength conversion member 84.

When the light emitting module 80 is manufactured, the first light wavelength conversion member 84 and the second light wavelength conversion member 86 are first laminated one on another by fixing them together with adhesive, etc., thereby forming the light wavelength conversion unit 82. Subsequently, the light wavelength conversion unit 82 is attached to the semiconductor light emitting element 88 by fixing the first light wavelength conversion member 84, the wavelength of light converted by which is longer, to the light emitting surface 88a of the semiconductor light emitting element 88 with adhesive, etc. Thereby, the light wavelength conversion unit 82 can be attached to the semiconductor light emitting element 88 such that the light emitted by the semiconductor light emitting element 88 sequentially passes through the first light wavelength conversion member 84 and the second light wavelength conversion member 86 in this order.

The third embodiment is the same as the first embodiment in that: a space may be provided between the first light wavelength conversion member 84 and the semiconductor light emitting element 88; and a reflective layer may be provided on each of the side surfaces of the first light wavelength conversion member 84 and the second light wavelength conversion member 86.

### Fourth Embodiment

FIG. 7 is a side view of a light emitting module 100 according to a fourth embodiment. The configuration of an automotive headlamp 10 is the same as that of the first embodiment, except that the light emitting module 100 is provided instead of the light emitting module 40. Hereinafter, the parts similar to the first embodiment will be denoted with the same reference numerals and descriptions thereof will be omitted.

The light emitting module 100 is formed in the same way as the light emitting module 80 according to the third embodiment, except that a light wavelength conversion unit 102 is provided instead of the light wavelength conversion unit 82. The light wavelength conversion unit 102 has a first light wavelength conversion member 104, a second light wavelength conversion member 106, and a third light wavelength conversion member 108. The first light wavelength conversion member 104, the second light wavelength conversion member 106, and the third light wavelength conversion member 108 are the same as the first light wavelength conversion member 54 and the second light wavelength conversion member 56 in that: they are made of fluorescent ceramic; they are formed to be plate-shaped and transparent; and they are composed of an inorganic substance free of an organic binder, etc.

The first light wavelength conversion member 104 converts the wavelength of the ultraviolet light mainly emitted by the semiconductor light emitting element 88 to emit red light. The second light wavelength conversion member 106 converts the wavelength of the ultraviolet light to emit green light. The third light wavelength conversion member 108 converts the wavelength of the ultraviolet light to emit blue light. Thus, each of the first light wavelength conversion member 104, the second light wavelength conversion member 106, and the third light wavelength conversion member 108 converts the wavelength of the light emitted by the semiconductor light emitting element 88 to emit the light within a wavelength range different from each other. Accordingly, white light, synthesized light made from: the red light whose wavelength has been converted by the first light wavelength conversion member 104 to be emitted; the green light whose wavelength has been converted by the second light wavelength conversion member 106 to be emitted; and the blue light whose wavelength has been converted by the third light wavelength conversion member 108, is emitted from the light emitting module 100.

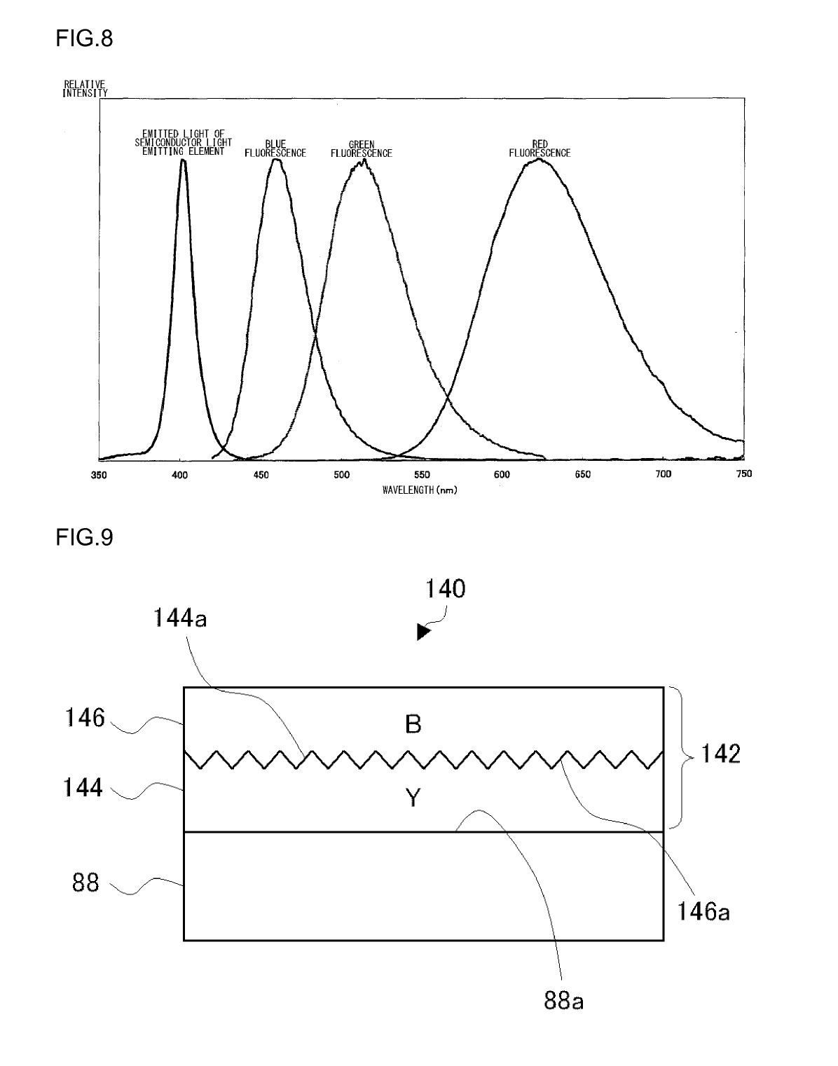

FIG. 8 is a graph illustrating an emission spectrum of each of the semiconductor light emitting element 88, the first light wavelength conversion member 104, the second light wavelength conversion member 106, and the third light wavelength conversion member 108. In FIG. 8, “Red Fluorescence” indicates the emission spectrum of the first light wavelength conversion member 104, “Green Fluorescence” indicates that of the second light wavelength conversion member 106, and “Blue Fluorescence” indicates that of the third light wavelength conversion member 108. As illustrated in FIG. 8, the emission spectrum of each of the semiconductor light emitting element 88, the first light wavelength conversion member 104, the second light wavelength conversion member 106, and the third light wavelength conversion member 108 has a single mount shape. The average wavelength of the emission spectrum of the third light wavelength conversion member 108 is longer than that of the emission spectrum of the semiconductor light emitting element 88. Further, the average wavelength of the emission spectrum of the second light wavelength conversion member 106 is longer than that of the emission spectrum of the third light wavelength conversion member 108. Furthermore, the average wavelength of the emission spectrum of the first light wavelength conversion member 104 is longer than that of the emission spectrum of the second light wavelength conversion member 106.

Referring back to FIG. 7, each of the first light wavelength conversion member 104, the second light wavelength conversion member 106, and the third light wavelength conversion member 108 is laminated such that the light emitted by the semiconductor light emitting element 88 passes through each of them in descending order of the average wavelength of the light whose wavelength has been converted, in order to avoid that the wavelength of light, which has once been converted, may be converted again, also in the fourth embodiment. The wavelength of green light is longer than that of blue light, and the wavelength of red light is longer than that of green light. Accordingly and specifically, the first light wavelength conversion member 104 for emitting red light by converting a wavelength is arranged above the light emitting surface 88a of the semiconductor light emitting element 88, the second light wavelength conversion member 106 is arranged further above the first light wavelength conversion member 104, and the third light wavelength conversion member 108 is still further above the second light wavelength conversion member 106.

When the light emitting module 100 is manufactured, the first light wavelength conversion member 104 and the second light wavelength conversion member 106 are first fixed together with adhesive, etc., and then the second light wavelength conversion member 106 and the third light wavelength conversion member 108 are fixed together with adhesive, etc. Thus, the light wavelength conversion unit 102 is formed in which the first light wavelength conversion member 104 and the second light wavelength conversion member 106 have been laminated one on another. Subsequently, the light wavelength conversion unit 102 is attached to the semiconductor light emitting element 88 by fixing the first light wavelength conversion member 104, the wavelength of light converted by which is longer, to the light emitting surface 88a of the semiconductor light emitting element 88 with adhesive, etc. Thereby, the light wavelength conversion unit 102 can be attached to the light emitting surface 88a of the semiconductor light emitting element 88 such that the light emitted by the semiconductor light emitting element 88 sequentially passes through the first light wavelength conversion member 104, the second light wavelength conversion member 106, and the third light wavelength conversion member 108 in this order.

The fourth embodiment is the same as the first embodiment in that: a space may be provided between the first light wavelength conversion member 104 and the semiconductor light emitting element 88; and a reflective layer may be provided on each of the side surfaces of the first light wavelength conversion member 104, the second light wavelength conversion member 106, and the third light wavelength conversion member 108.

### Fifth Embodiment

FIG. 9 is a side view of a light emitting module 140 according to a fifth embodiment. The configuration of an automotive headlamp 10 is the same as that of the first embodiment, except that the light emitting module 140 is provided instead of the light emitting module 40. Hereinafter, the parts similar to the first embodiment will be denoted with the same reference numerals and descriptions thereof will be omitted.

The light emitting module 140 is formed in the same way as the light emitting module 80 according to the third embodiment, except that a light wavelength conversion unit 142 is provided instead of the light wavelength conversion unit 82. The light wavelength conversion unit 142 has a first light wavelength conversion member 144 and a second light wavelength conversion member 146. The material of the first light wavelength conversion member 144 is the same as that of the aforementioned first light wavelength conversion member 84. Accordingly, the first light wavelength conversion member 144 converts the wavelength of the ultraviolet light mainly emitted by the semiconductor light emitting element 88 to emit yellow light. The material of the second light wavelength conversion member 146 is the same as that of the aforementioned second light wavelength conversion member 86. Accordingly, the second light wavelength conversion member 146 converts the wavelength of the ultraviolet light to emit blue light.

The light wavelength conversion unit 142 is formed by bonding together the first light wavelength conversion member 144 and the second light wavelength conversion member 146. Each of the first light wavelength conversion member 144 and the second light wavelength conversion member 146 has concavities and convexities in the bonded portion. Specifically, concavities and convexities are provided on each of the emitting surface 144a of the first light wavelength conversion member 144 and the incident surface 146a of the second light wavelength conversion member 146. A bonded portion having concavities and convexities is formed by fixing together the emitting surface 144a and the incident surface 146a with adhesive. By providing concavities and convexities in the bonded portion, as stated above, light is more likely to enter the second light wavelength conversion member 146 from the first light wavelength conversion member 144, thereby allowing the extraction efficiency of light to be enhanced. When three layers or more of light wavelength conversion members are laminated, at least one pair of the members to be bonded together may have concavities and convexities in the bonded portion between them.

### Sixth Embodiment

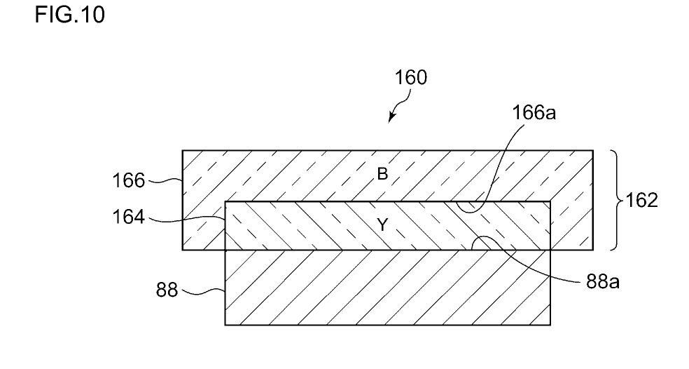

FIG. 10 is a sectional view of a light emitting module 160 according to a sixth embodiment. The configuration of an automotive headlamp 10 is the same as that of the first embodiment, except that the light emitting module 160 is provided instead of the light emitting module 40. Hereinafter, the parts similar to the first embodiment will be denoted with the same reference numerals and descriptions thereof will be omitted.

The light emitting module 160 is formed in the same way as the light emitting module 80 according to the third embodiment, except that a light wavelength conversion unit 162 is provided instead of the light wavelength conversion unit 82. The light wavelength conversion unit 162 has a first light wavelength conversion member 164 and a second light wavelength conversion member 166. The material of the first light wavelength conversion member 164 is the same as that of the aforementioned first light wavelength conversion member 84. Accordingly, the first light wavelength conversion member 164 converts the wavelength of the ultraviolet light mainly emitted by the semiconductor light emitting element 88 to emit yellow light. The material of the second light wavelength conversion member 166 is the same as that of the aforementioned second light wavelength conversion member 86. Accordingly, the second light wavelength conversion member 166 converts the wavelength of the ultraviolet light to emit blue light.

The second light wavelength conversion member 166 is provided so as to cover approximately the whole area of the light emitting portion in the first light wavelength conversion member 164 through which the light emitted by the semiconductor light emitting element 88 passes last. Specifically, the second light wavelength conversion member 166 is formed to be wider than the first light wavelength conversion member 164 and a concaved portion 166a is provided on one surface thereof. The concave portion 166a is formed to have the same outer shape and depth as those of the first light wavelength conversion member 164. The light wavelength conversion unit 162 is formed by housing the first light wavelength conversion member 164 into the concave portion 166a and by fixing them together with adhesive, etc. The light wavelength conversion unit 162 is attached to the semiconductor light emitting element 88 by fixing the exposed surface of the first light wavelength conversion member 164 to the light emitting surface 88a of the semiconductor light emitting element 88 with adhesive. Thus, all the outer surfaces of the first light wavelength conversion member 164 other than the incident surface are covered with the second light wavelength conversion member 166.

Because the semiconductor light emitting element 88 emits ultraviolet light, it is desirable that the wavelength of most of the ultraviolet light is converted. Thereby, the light that has passed through the first light wavelength conversion member 164 and that will be emitted outward without passing through the second light wavelength conversion member 166 can be suppressed.

The present invention should not be limited to the above embodiments, and variations in which each component of the embodiments is appropriately combined are also effective as embodiments of the invention. Various modifications, such as design modifications, can be made with respect to the above embodiments based on the knowledge of those skilled in the art. Such modified embodiments can also fall in the scope of the invention.

### INDUSTRIAL APPLICABILITY

The present invention is applicable to a light emitting module, a method of manufacturing the light emitting module, and a lamp unit comprising the light emitting module.

1. A light emitting module comprising:
a light emitting element; and
a plurality of light wavelength conversion members each of which converts the wavelength of the light emitted by the light emitting element to emit light within a wavelength range different from the others, wherein
each of the plurality of light wavelength conversion members is formed into a plate shape before the lamination thereof and is laminated such that the light emitted by the light emitting element sequentially passes through each of the members.

2. The light emitting module according to claim 2, wherein
each of the light wavelength conversion members is formed to be so transparent that the total light transmittance of the light within a conversion wavelength range is 40 percent or more.

3. The light emitting module according to claim 1 or claim 2, wherein
the plurality of light wavelength conversion members are laminated one on another such that the light emitted by the light emitting element passes through the members in descending order of the average wavelength of the light whose wavelength has been converted.

4. The light emitting module according to any one of claims 1 to 3, wherein
among the plurality of light wavelength conversion members, at least one of the members through which the light emitted by the light emitting element passes for the second time or later is provided so as to cover approximately the whole area of the light emitting portion in the light wavelength conversion member through which the light emitted by the light emitting element passes last.

5. The light emitting module according to any one of claims 1 to 4, wherein
among the plurality of light wavelength conversion members, at least one pair of the members to be bonded together have concavities and convexities in the bonded portion between the members.

6. A method of manufacturing a light emitting module comprising:
laminating, one on another, a plurality of light wavelength conversion members each of which is formed into a plate shape and each of which converts the wavelength of the incident light to emit the light within a wavelength range different from the others; and
arranging the plurality of light wavelength conversion members thus laminated such that the light emitted by a light emitting element sequentially passes through each of the members.

7. A lamp unit comprising:
a light emitting module including a light emitting element and a plurality of light wavelength conversion members each of which converts the wavelength of the light emitted by the light emitting element to emit the light within a wavelength range different from the others; and
an optical member configured to collect the light emitted by the light emitting module, wherein
each of the plurality of light wavelength conversion members is formed into a plate shape and is laminated such that the light emitted by the light emitting element sequentially passes through each of the members.
